(19) United States
(12) Patent Application Publication
(10) Pub. No.: US 2021/0126523 A1
(43) Pub. Date: Apr. 29, 2021

(54) ELECTRIC POWER CONVERSION SYSTEM

(71) Applicant: Tong Chen, San Jose, CA (US)

(72) Inventor: Tong Chen, San Jose, CA (US)

(21) Appl. No.: 17/139,781

(22) Filed: Dec. 31, 2020

Related U.S. Application Data
(60) Provisional application No. 62/963,088, filed on Jan. 19, 2020.

(51) Int. Cl. H02M 1/32; G08B 21/02; G01R 31/52

(52) U.S. Cl. CPC H02M 1/32; G01R 31/52; G08B 21/02

(57) ABSTRACT

Disclosed is a power conversion system for notifying electrical faults and protection against electrical shocks. The power conversion system includes a first circuit having a primary winding; a second circuit having a secondary winding, and a core, wherein the primary winding and the secondary winding are coiled around the core. The power conversion system further includes an impedance and a detection module in series bridged to the first circuit and the second circuit forming the third circuit. The detection module is configured to detect any fault electrical current flowing from the first circuit to the second circuit via the third circuit. The detection module is connected to an alert unit for indicating the presence of fault current in the third circuit and optionally the detector module may also connect to a circuit breaker.

### FIELD OF INVENTION

The present invention relates to a power conversion system, and more particularly to a power conversion system that monitors and alarms about an electrical fault and prevent consequent harms to human.

### BACKGROUND

Electric shock is one of the most common and dangerous hazards to human, especially to persons who are lack of self-protection capabilities, e.g., children, patients. A variety of methods have been invented in prior arts to address this problem in multiple aspects. However, this problem has not been completely resolved due to various issues. Electrical distribution systems for the places of high safety requirements (e.g., home, hospital) usually have installed protective devices, such as fuses and residual-current devices (RCD), to protect human by interrupting the power supply before causing permanent harms. However, interrupting the power supply, sometimes cannot be performed quickly enough to safeguard against the shock. The reasons can be failure of components, aging electrical elements, low detection sensitives, etc., which poses life-threatening danger to human. Even if shutting down of the appliance is performed immediately, indirect injuries may still occur in some cases, (e.g., falling after receiving a shock). In addition, the protective device that oversees the entire electrical distribution system shuts down the entire power supply system when any fault occurs without the capability of identifying misfunctioning appliances, which affects the functioning appliances as well. Although advanced monitoring/protective devices have been invented in prior arts to improve reliability and robustness, it substantially increases cost, complexity, and maintenance in implementation.

Electric outlets exposed to children at home present considerable risks of electric shock to children. Although advanced electric outlets include protective features, such as ground-fault circuit interrupter (GFCI) receptacles, outlets with covers, etc., they cannot eliminate such risks but increase cost, complexity, and maintenance in implementation.

Although an increasing number of appliances/equipment include three-pole plug which helps personal protection, a lot of appliances (with associated power adapters) are still using two-pole plugs (i.e., do not include ground pin), which limit protection features/capabilities.

A long standing need is there for a power conversion system which serves as an interface between mains electricity and various appliances/equipment in the places of high safety requirements and the associated methods to prevent electric shock, which overcomes at least one of the disadvantages of the prior arts or improve at least one of the disadvantageous aspects of the prior arts, or to provide a constructive and useful alternative.

### SUMMARY OF THE INVENTION

The principal object of the present invention is therefore directed to a power conversion system which serves as an interface between mains electricity and various appliances/equipment in the places of high safety requirements.

It is a further object of the present invention that the system prevents accidental electrical shocks to a human, regardless a) the presence/absence of protective devices/features in the electrical distribution systems, electric outlets, appliances, and b) the types of the appliance plugs (i.e., two-pole or three-pole).

It is another object of the present invention that the system is economical to manufacture.

It is still another object of the present invention that the system is economical to maintain.

It is yet another object of the present invention that the system provides automated notification of electrical faults.

In one aspect, disclosed is an electric power conversion system for electrical fault detection, notification, and prevention. The disclosed electric power conversion system includes a first circuit having a primary winding, the first circuit electrically connected to an ac input; a second circuit having a secondary winding, the second circuit electrically connected to an ac or dc output. The electric power conversion system also includes an iron core, wherein the primary winding, and the secondary winding are coiled around the iron core. An impedance and a detector are connected in series across the first circuit and the second circuit forming a third circuit. The impedance configured to depress any fault current flowing from the first circuit to the second circuit via the third circuit. The detector configured to detect any fault current occurred in the third circuit.

These and other objects and advantages of the embodiments herein will become readily apparent from the following detailed description taken in conjunction with the accompanying drawings.

### BRIEF DESCRIPTION OF THE DRAWINGS

The accompanying figures, which are incorporated herein, form part of the specification and illustrate embodiments of the present invention. Together with the description, the figures further explain the principles of the present invention and to enable a person skilled in the relevant arts to make and use the invention.

FIG. 1 shows one embodiment of the power conversion system, according to an exemplary embodiment of the present invention.

FIG. 2 shows another embodiment of the power conversion system, according to an exemplary embodiment of the present invention.

FIG. 3 shows another embodiment of the power conversion system, according to an exemplary embodiment of the present invention.

FIG. 4 shows another embodiment of the power conversion system, according to an exemplary embodiment of the present invention.

FIG. 5 shows another embodiment of the power conversion system, according to an exemplary embodiment of the present invention.

FIG. 6 shows another embodiment of the power conversion system, according to an exemplary embodiment of the present invention.

FIG. 7 shows another embodiment of the power conversion system, according to an exemplary embodiment of the present invention.

FIG. 8 shows another embodiment of the power conversion system, according to an exemplary embodiment of the present invention.

### DETAILED DESCRIPTION

Subject matter will now be described more fully hereinafter with reference to the accompanying drawings, which form a part hereof, and which show, by way of illustration, specific exemplary embodiments. Subject matter may, however, be embodied in a variety of different forms and, therefore, covered or claimed subject matter is intended to be construed as not being limited to any exemplary embodiments set forth herein; exemplary embodiments are provided merely to be illustrative. Likewise, a reasonably broad scope for claimed or covered subject matter is intended. Among other things, for example, the subject matter may be embodied as methods, devices, components, or systems. The following detailed description is, therefore, not intended to be taken in a limiting sense.

The word “exemplary” is used herein to mean “serving as an example, instance, or illustration.” Any embodiment described herein as “exemplary” is not necessarily to be construed as preferred or advantageous over other embodiments. Likewise, the term “embodiments of the present invention” does not require that all embodiments of the invention include the discussed feature, advantage, or mode of operation.

The terminology used herein is for the purpose of describing particular embodiments only and is not intended to be limiting of embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

The following detailed description includes the best currently contemplated mode or modes of carrying out exemplary embodiments of the invention. The description is not to be taken in a limiting sense but is made merely for the purpose of illustrating the general principles of the invention, since the scope of the invention will be best defined by the allowed claims of any resulting patent.

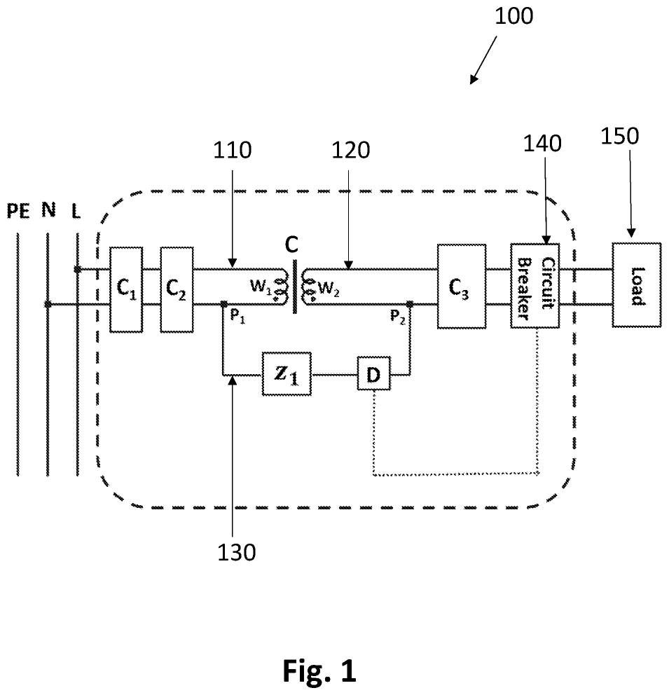

Referring to FIG. 1, which shows an exemplary embodiment of the disclosed electrical power conversion system. The electric power conversion system 100 includes a module C1 which can be electrically connected to a mains input voltage supply (shown in FIG. 1 connected to Live and Neutral). The module C1 can convert power from standard mains AC to DC power of a predetermined voltage level. The output of the module C1 can be electrically connected to an input of a module C2. The module C2 can convert the DC power from the module C1 to an AC power of predetermined frequency and voltage amplitude for the transformer (the primary winding W1). Another module C3 can convert the AC power from the secondary windings W2 of the transformer to an AC power of predetermined frequency and voltage amplitude or an DC power of predetermined ratings for the load. The transformer includes a first circuit 110 having the primary winding W1 and second circuit 120 having a secondary winding W2, wherein the primary winding and the secondary winding can be coiled around a core C of the transformer. A third circuit bridged across the first circuit and the second circuit. The third circuit having an impedance Z1 and a detection module D in series connection. The detection module D can detect a change of current passing through the impedance Z1. The detection module D can electrically connect to an alert unit. The detector module can also electrically connect to a circuit breaker 140, wherein the circuit breaker interposed between the module C3 and a load 150.

In one implementation, the detection module D can include a current transformer. In absence of any electrical fault in the power conversion system 100 or the load 150 connected to the power conversion system 100, no current passes through the impedance Z1. Any ground fault or an electric shock occurring at the side of load 150, causes a current passing through the impedance Z1. The large impedance Z1 limits the current to an adequately small value that is not dangerous to humans. Such a current can be detected by the detection module D. The module D upon detecting the current can trigger the alert unit indicating the fault. In case, module D is connected to a circuit breaker via a data link illustrated by the dotted line shown in FIG. 1, the module D can send a signal to the circuit breaker to break the circuit electrically disconnecting the load from the disclosed power conversion system. The node P1 shows the connection between the third circuit and the first circuit, while the node P2 shows the connection between the third circuit and the second circuit. The node P1 can be anywhere on the first circuit. Similarly, the node P2 can be anywhere on the second circuit.

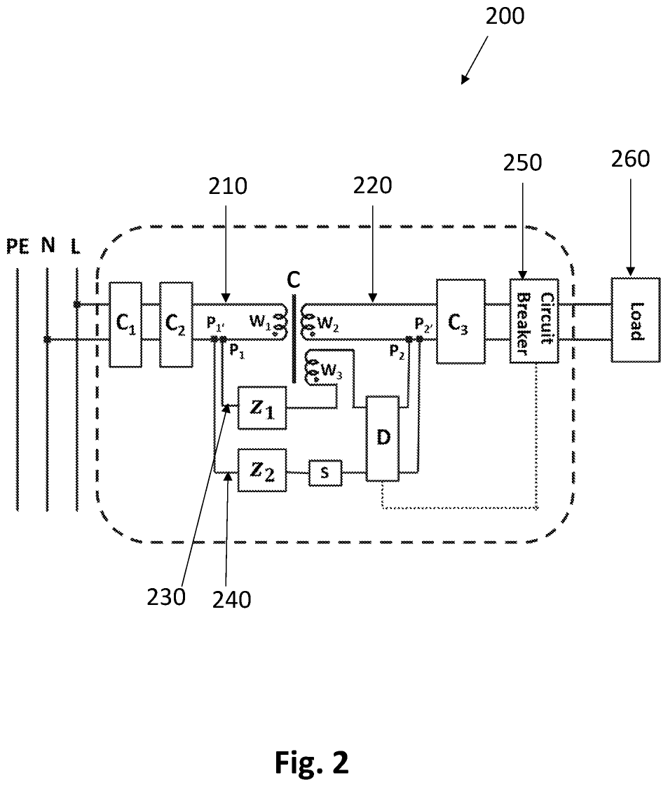

Referring to FIG. 2, which shows another embodiment of the power conversion system 200. The disclosed electric power conversion system 200 includes a module C1 which can be electrically connected to a mains input voltage supply. The module C1 can convert power from standard mains AC to DC power of a predetermined voltage level. The output of the module C1 can be electrically connected to an input of a module C2. The module C2 can convert the DC power from the module C1 to an AC power of predetermined frequency and voltage amplitude for the transformer (the primary winding W1). Another module C3 can convert the AC power from the secondary windings W2 of the transformer to an AC power of predetermined frequency and voltage amplitude or an DC power of predetermined ratings for the load.

A first circuit 210 can receive AC power from the module C2. The first circuit 210 has in series the primary winding W1. The second circuit 220 in electrical connection with the module C3, wherein the second circuit 220 having the winding W2 in series connection. The primary winding W1 and the secondary winding W2 coiled around the core C. The disclosed power conversion system 200 further includes a third circuit 230 bridged across the first circuit 210 at P1 and the second circuit 220 at P2. The third circuit 230 has the impedance Z1 and the winding W3 in series connection. The winding W3 coiled around the core C. Fourth circuit 240 is electrically bridged across the first circuit 210 at P1′ and the second circuit 220 at P2′. The fourth circuit 240 having the impedance Z2 and a sensor S in series connection. Furthermore, both the third circuit and the fourth circuit having in series connection to the detector D. The detector can further be connected to an alert unit and circuit breaker 250. The circuit breaker 250 electrically interposed between the circuit breaker 250 and the load 260.

Against referring to FIG. 2, the third circuit 230 and the fourth circuit 240 are parallel, wherein the impedance Z1 is parallel to the impedance Z2. The detection module D connected across the wires connecting the impedance Z1 and Z2, as shown in FIG. 2, can detect any net current passing through the module D. One of the examples of module D is a current transformer. A sensor module S is connected in series of the impedance Z2 can monitor the presence/absence of current passing through the impedances Z1 and Z2. In the absence of any electrical fault or shock, the current passing through the impedances Z1 and Z2 are balanced (i.e., the amplitudes are the same, but the directions are opposite.) Thus, there is no net current passes through module D. The presence of current passing through the impedances Z1 and Z2 are monitored and indicated by module “S”. When a ground fault or an electric shock occurs at the side of load 260, the current passing the impedance Z1 and Z2 are in the same direction, and thus there is a net current passing through the module D. The large impedance Z1 and Z2 limit the current to an adequately small value, which is not dangerous to humans. Module D includes a function of alarm, which indicates the fault when a net current is detected. Optionally, module D can be connected to a circuit breaker 250 via a data link illustrated by the dotted line shown in FIG. 2.

Any electrical error or shock can cause an imbalance of current passing through the impedances Z1 and Z2 (e.g., any short circuit occurs between primary W1 and secondary W2 windings, between primary W1 and tertiary W3 winding, between secondary W2 and tertiary W3 windings) of FIG. 2, there is a net current passing through the module D which triggers the alarm and optionally sends a signal to the circuit breaker to break the circuit. When any error occurred causes the absence of current passing through the impedances Z1 and Z2, (e.g., any wires connecting to the impedances Z1 and Z2 is broken, or any nodes P1, P1′, P2 and P2′ is disconnected, etc.), such absence of the current passing through the impedances Z1 and Z2 is detected and indicated by the module S (i.e., indicating that the power conversion system is not working properly).

It is to be understood that the nodes P1 and P1′ should be at equal potential, which can be located at any point of the first circuit. The nodes P2 and P2′ should be at equal potential, which can be located at any point of the second circuit. The module S can be connected in series with either the impedance Z1 or Z2.

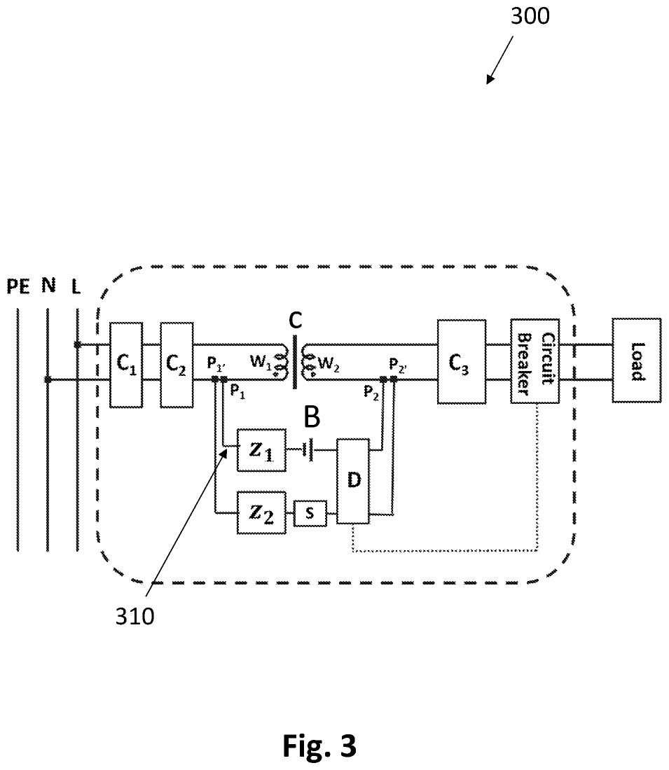

Referring to FIG. 3, which shows an alternate embodiment of the power conversion system 200. The power conversion system 300 can have a third circuit 310 in which tertiary winding W3 has been substituted with an independent power supply, such as batteries B.

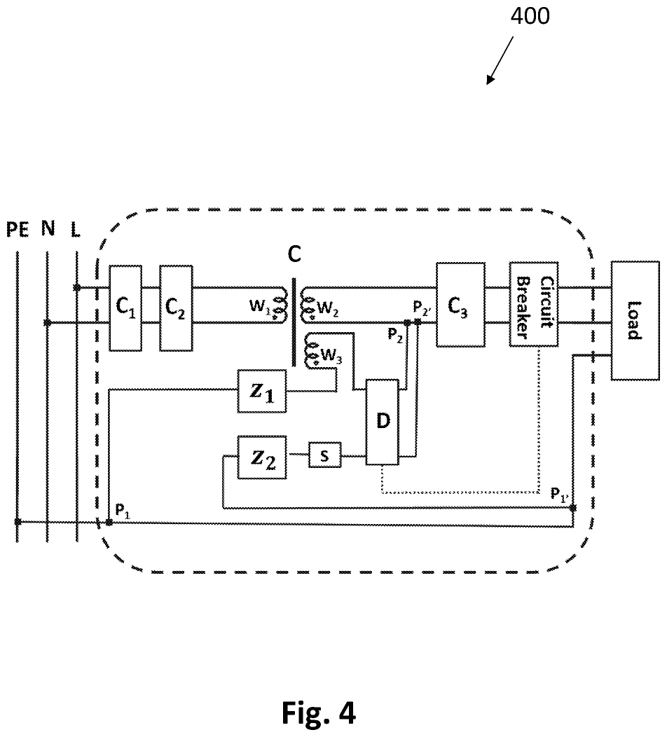

Referring to FIG. 4 which shows an alternate embodiment of the power conversion system 200. The power conversion system 400 can include nodes P1 and P1′ electrically attached to the wire connecting to the protective earth (PE) wire of mains electricity. The third circuit and the fourth circuit bridges across the secondary winding and the protective earth wire.

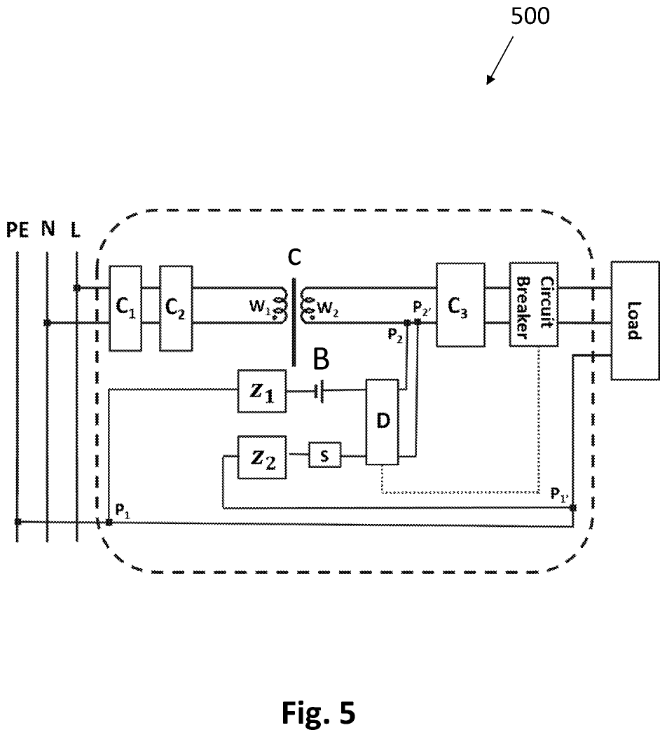

Referring to FIG. 5, which shows an alternate embodiment of the power conversion system 400. The power conversion system 500 having the tertiary winding W3 replaced by an independent power supply, such as battery B

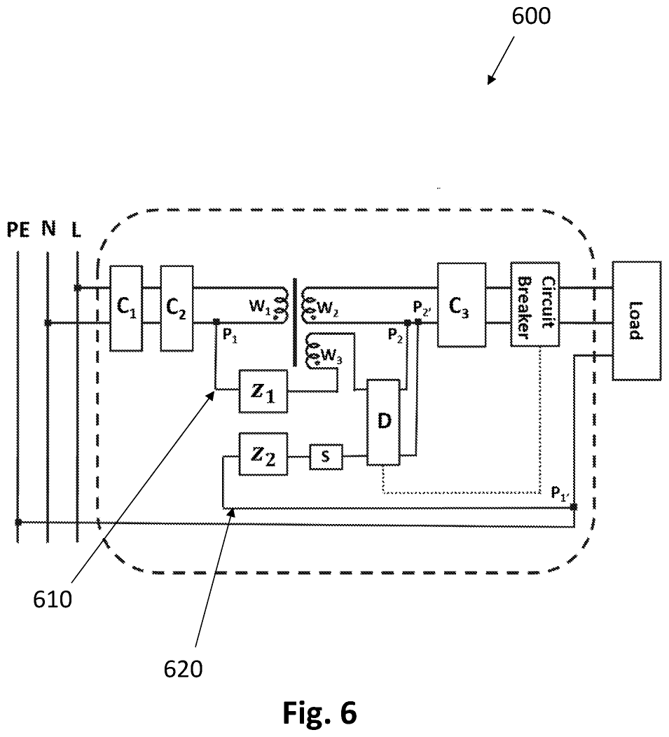

Referring to FIG. 6, which shows an alternate embodiment of the power conversion system 200. The power conversion system 600 includes the third circuit 610 bridged across the first circuit at P1 and the second circuit at P2. The fourth circuit 620 bridged across the second circuit 630 at node P2′ and the PE wire at P1′.

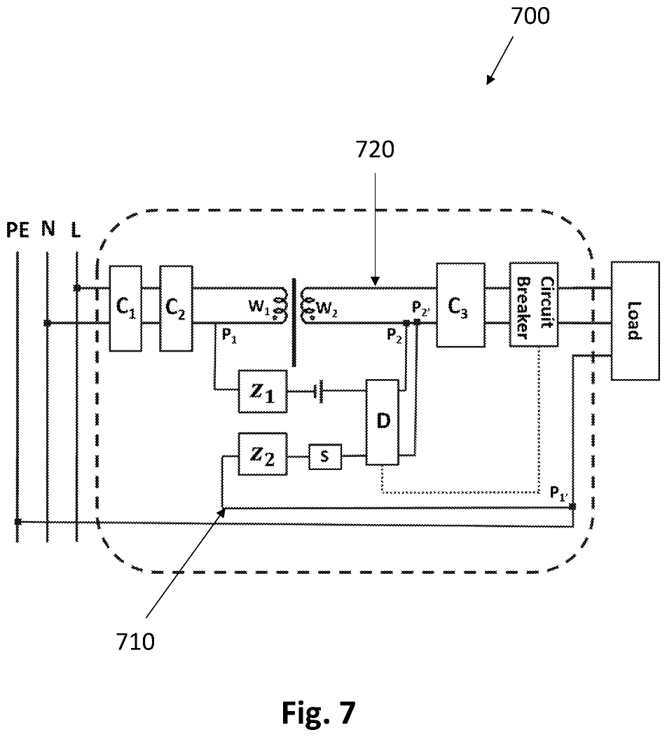

Referring to FIG. 7 which shows an alternate embodiment of the power conversion system 300 shown in FIG. 3. The disclosed powered system has the fourth circuit 710 that bridges across the second circuit 720 at node P2′ and the wire PE at node P1′.

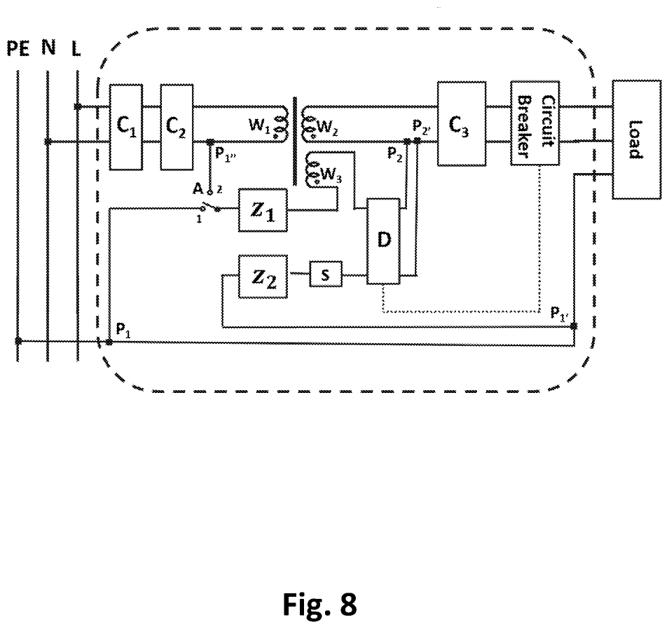

Now referring to FIG. 8, which shows an alternate embodiment of the power conversion system 400 shown in FIG. 4. The disclosed power conversion system 800 having the impedance Z1 connected in series to the first circuit and the PE wire separately via a switch A. When switch A is at “1” position, the impedance Z1 is connected to the PE wire at the node of P1, being equivalent to the power conversion system 400. When switch A is at the “2” position, the impedance Z1 is connected to the first circuit at the node of P1″, which is equivalent to the power conversion system 600 of FIG. 6.

While the foregoing written description of the invention enables one of ordinary skill to make and use what is considered presently to be the best mode thereof, those of ordinary skill will understand and appreciate the existence of variations, combinations, and equivalents of the specific embodiment, method, and examples herein. The invention should therefore not be limited by the above-described embodiment, method, and examples, but by all embodiments and methods within the scope and spirit of the invention as claimed.

What is claimed is:

1. A power conversion system comprising:
a first circuit having a primary winding;
a second circuit having a secondary winding;
a core, wherein the primary winding and the secondary winding are coiled around the core; and
a first impedance connected between the first circuit and the second circuit forming a third circuit as a first bridge circuit.

2. The power conversion system according to claim 1 wherein the first impedance depresses a fault current flowing from the first circuit to the second circuit via the third circuit to an insignificant value.

3. The power conversion system according to claim 1, wherein the power conversion system further comprises a detection module electrically connect to the first impedance of the third circuit in series to detect a fault current flowing from the first circuit to the second circuit via the third circuit.

4. The power conversion system according to claim 3, wherein the detection module is connected to an alert unit, wherein detection module is configured to trigger the alert unit upon detecting the change in the current on the third circuit.

5. The power conversion system according to claim 4, wherein the alert unit is visual and/or audio alarm device.

6. The power conversion system according to claim 1, wherein the first circuit further comprises an AC to DC converter module configured to electrically connect with a main ac power supply and a DC to AC converter module electrically connected to the primary winding.

7. The power conversion system according to claim 3, wherein the second circuit further comprises a third power module configured to electrically connect the secondary winding to a load, which converts the ac power from the secondary winding to a suitable ac or dc power for the load. [claim 9 depends on claim 7, which includes a detection module recited by claim 3, so claim 7 should depend on claim 3]

8. The power conversion system according to claim 3, wherein the detection module is an electrical transformer.

9. The power conversion system according to claim 7, wherein the second circuit further comprises a circuit breaker electrically connected to an output of the third power module, the circuit breaker operably connected to the detection module, wherein the detection module upon detecting the fault current triggers the circuit breaker.

10. The power conversion system according to claim 1, wherein the power conversion system further comprises a tertiary winding and a second impedance connected in series between the first circuit and the second circuit forming a fourth circuit as a second bridge circuit in parallel with the third circuit, the tertiary winding is coiled around the core.

11. The power conversion system according to claim 10, wherein the power conversion system further comprises a detector module connected in series on the third circuit and the fourth circuit.

12. The power conversion system according to claim 11, wherein the power conversion system further comprises a sensor in series connection with the first impedance and between the first impedance and the detector module, the sensor configured to monitor the current in a loop formed by the third circuit and the fourth circuit. [detector module is recited in claim 11, so it must depend from claim 11, we have to remove this statement to make it dependent on claim 10]

13. The power conversion system according to claim 10 wherein the first impedance and the second impedance depresses a current in the third circuit and the fourth circuit to an insignificant value.

14. The power conversion system according to claim 11 wherein the detector module is configured to measure any net fault current flowing from the first circuit to the second circuit via the third circuit and the fourth circuit.

15. The power conversion system according to claim 1, wherein the power conversion system further comprises a tertiary winding and a second impedance connected in series between the earth line and the second circuit forming a fourth circuit as a second bridge circuit, the tertiary winding is coiled around the core.

16. The power conversion system according to claim 1, wherein the power conversion system further comprises a battery and a second impedance connected in series between the earth line and the second circuit forming a fourth circuit as a second bridge circuit.

17. The power conversion system according to claim 1, wherein the power conversion system further comprises a battery and a second impedance connected in series between the first circuit and the second circuit forming a fourth circuit as a second bridge circuit in parallel with the third circuit.

18. The power conversion system according to claim 12 wherein the sensor is LED.

19. The power conversion system according to claim 11, wherein the power conversion system further comprises a sensor in series connection and between the second impedance and the tertiary winding, the sensor configured to detect presence of a current in a loop formed by the third circuit and the fourth circuit. [dependence from claim 11 is correct, making the claim a combination claims 1, 10, 11, and 19]
